(19) United States
(12) Patent Application Publication
(10) Pub. No.: US 2003/0217324 A1
(43) Pub. Date: Nov. 20, 2003

(54) System and method for communicating between a number of elements and a method for configuring and testing the system

(76) Inventors: Peter Ostergaard Nielsen, Lyngby (DK); Jens P. Tagore-Brage, Frederiksberg (DK)

Correspondence Address: HARNESS, DICKEY & PIERCE, P.L.C., P.O. Box 8910, Reston, VA, 20195, US

(21) Appl. No.: 10/289,227

(22) Filed: Nov. 7, 2002

Related U.S. Application Data
(60) Provisional application No. 60/332,943, filed on Nov. 7, 2001.

(51) Int. Cl. H03M 13/00

(52) U.S. Cl. 714/776

(57) ABSTRACT

A switch chip where the parts taking up the most space on the die are provided with a redundancy in number so that a malfunctioning or weak element may be circumvented or routed around so that the chip may be fully functional even though one of the elements is malfunctioning. Means are provided for facilitating communication between the ports of the switch, the functioning elements and a common bus for transferring data between the elements and ports. The malfunctioning or redundant element may be rendered inactive by removing power or a clocking signal thereto. Manners of configuring and testing the chip are described as well as the use of the chip for providing lower functionality configurations.

The present invention relates to the providing of additional or redundant elements in systems, such as chips, in order to be able to route around or work around malfunctioning elements.

In normal chip manufacture, it is known that a die may fail due to an error therein. The larger the die, the larger the possibility of an error occurring on the die.

In memory chips, it is normal to provide additional memory blocks and then, during testing, determine which blocks are good and which are defect and thereafter, during the packaging, employ only the good memory blocks. The testers used for this purpose are complicated testers, which must be able to control a laser in order to blow fuses to route around the malfunctioning memory blocks.

The present invention relates to the providing of redundant elements not in “simple” memory chips or systems but in more complicated communication chips or systems. Also, an aspect of the invention aims at being able to use simpler testers, which simply provide a GO or a NOGO to each die.

Redundancy etc. may be seen in e.g. U.S. Pat. Nos. 5,530,694, 6,034,536, 6,337,578, 5,144,230, 6,385,747, 6,347,378, and 6,344,755.

In a first aspect, the invention relates to a system for communicating between a number of elements via a data bus, the system comprising:

a data bus,

a first number, n1, of devices adapted to interchange data on the data bus,

a second number, n2, of elements each adapted to communicate with one of the devices, n1≦n2,

a third number, n3, of input/output ports each adapted to communicate with one or more external computers or networks and to communicate with one of the second number of elements, n3<n2,

means for identifying n3 of the elements which are to be used,

first means for facilitating communication between pairs of one of the n3 elements and one of the n1 devices, and

second means for facilitating communication between pairs of one of the n3 elements and one of the n3 I/O ports.

In general, the present system may be e.g. a switch/router/hub type element where frames/packets/cells entering at an input port will be transferred to an output port via two elements, two devices, and the bus. Naturally, e.g. a switch would normally have both look-up facilities, an arbiter, etc. These elements may also be provided in duplicate, e.g. in order to provide an even larger probability of manufacturing a working system.

The most important number to keep constant in systems of this type, especially when manufactured as a single chip or a number of chips, is the number of ports. This relates to the fact that the pin-out of a chip is preferably the same for all chips having the same functionality. Otherwise, providing redundant ports would require the board manufacturer to prepare boards for each combination of good/bad ports. This is not desirable. An aspect of the invention relates to the providing, from the same system/die, systems with different functionalities and different numbers of ports.

Thus, in the present embodiment, the ports are all considered active, and a larger number of elements is provided. The elements, thus, are provided with a redundancy. The ports will be those parts of the system through or via which other systems or elements communicate with the system.

In this connection, the elements “to be used” will normally be functional elements—but not necessarily all functional elements. A functional element may e.g. not be one “to be used” if it is not able to, via the facilitating means, to communicate with a suitable port or device.

In general, “communication” will mean that information may be exchanged between the device/element/port/means. Preferably, this communication will be a two-way communication.

The facilitating means will provide communication between the port and the element in a port/element pair and between the element and device in each element/device pair. Also, normally, if e.g. n3 elements are identified, n3 pairs of element/device and element/port are generated.

In the present context, n1-n10 (as will be mentioned later) are, naturally, integers.

Another aspect of the invention relates to a system for communicating between a number of elements via a data bus, the system comprising:

a data bus,

a first number, n1, of devices adapted to interchange data on the data bus by, repeatedly, a plurality of the devices forwarding data simultaneously to a next device on the data bus,

a second number, n2, of elements each adapted to communicate with one of the devices, n1≦n2,

a number, n3, of input/output ports each adapted to communicate with one or more external computers or networks and to communicate with one of the second number of elements,

means for identifying n4<n1 of the elements which are to be used, and

first means for facilitating communication between n4 pairs of one of the n4 elements and one of the n1 devices,

wherein a number of the n1 devices comprises:

means for delaying data received from the data bus before transmission thereof on the bus, and

means for circumventing the delaying means, and

wherein the identifying means are adapted to have the circumventing means circumvent the delaying means in those of the n1 devices not forming part of the n4 pairs.

In this context, “repeatedly” means that the step is performed a number of times in order to obtain a systolic behaviour of data transport on the bus. This type of data transport is normally unidirectional along the bus—but the bus may comprise two oppositely directed busses.

When introducing a delay, which is normal for attachment points on systolic busses, a reduction is seen in bandwidth on the bus if this “step” along the bus is also not used for introducing data. Thus, an empty slot is always present on the bus. In the present embodiment, it is instead desired to render the attachment point invisible—that is, avoid the delay all together in relation to elements, which are not to be used. In this manner, a fewer “steps” or slots exist along the bus—but all steps may be used for data transport which optimises the bandwidth on the bus.

In this embodiment, the devices may be adapted to:

select one or more data packets to be switched, each data packet being held by a respective device, and

repeatedly, a first number of times:

forward, at least substantially simultaneously, at least part of each of the data packets and pertaining receiving device information to a next device along the interconnecting means,

receive, at least substantially simultaneously and from the interconnecting means, the at least part of the selected data packets and the pertaining receiving device information, and

determine, at least substantially simultaneously in each device having received at least part of a data packet, on the basis of the pertaining receiving device information, whether the at least part of the data packet is intended for the device and, if so, storing a copy of the at least part of the data packet in the device.

This type of operation of the data bus may be seen from U.S. patent application No. 60/287,718, which is hereby incorporated by reference.

A third aspect relates to a testing system for testing a system comprising:

a data bus,

a first number, n1, of devices adapted to interchange data on the data bus,

a second number, n2, of elements each adapted to communicate with one of the devices,

a third number, n3, of input/output ports each adapted to communicate with one or more external computers or networks and to communicate with one of the second number of elements, n3<n2,

means for identifying n4 of the elements which are to be used,

first means for facilitating communication between pairs of one of the n4 elements and one of the n1 devices, and

second means for facilitating communication between pairs of one of the n4 elements and one of the n3 I/O ports,

the testing system comprising:

means for providing power to the system,

means for operating the identifying and facilitating means with n4=n3,

means for determining whether communication is possible from each of the n3 ports to the data bus in the powered system, and

means for, if not, operating the identifying and facilitating means with n4 being a value lower than n3.

In this embodiment, any type of data bus may in principle be used.

This testing system will firstly, upon providing power to the system, attempt a configuration with n3 active ports. If this configuration is not operative (communication from each active port to the bus), a configuration with a lower number of ports is tested.

Preferably, the means for operating the means for, if not, operating the identifying and facilitating means with n4 being a value lower than n3, are adapted to operate the identifying and facilitating means with n4 being one value of a predetermined set of values each being lower than n3. These sets may be different, predetermined numbers of active ports commonly used. Normal numbers of ports are: 4, 8, 12, 16, 24, 32 etc.

Also, normally, the elements and the ports are positioned in an at least substantially two-dimensional area of the system, where the ports are distributed along a perimeter of the area, where the sets are defined as sets of ports having predetermined positions along the perimeter of the area, and where the identifying means are adapted to identify n4 functional elements each being adapted to communicate with at least one of the ports of the set.

Thus, when the ports along the periphery have predetermined positions, bond-out of the system (as a single chip e.g.) is made easy. The usefulness of the facilitating means is now seen in that different operative elements may actually be used with the same bond-out. Thus, a given set of ports may use different elements—while still giving the same functionality.

Preferably, the identifying means are adapted to identify n4 functional elements each being adapted to communicate with only one of the ports of the set via the second facilitating means.

In a preferred embodiment, the means for operating the identifying and facilitating means with n4=n3 are adapted to set up a first configuration of the system having each of the n3 ports operable and wherein the facilitating means facilitate that:

each of a first number, n6, of the n3 ports can communicate with at least one element which can communicate with a plurality of the n5 ports and

each of a second number, n7, of the n3 ports can communicate with a plurality of elements, which can communicate with only that of the n3 ports.

In this context, if more than n3 ports are, in fact, operable or functional, n3 ports thereof are selected in any suitable manner.

In general, each element, device and port preferably is adapted to always only communicate with a single element, device and/or port. However, the facilitating means may make it possible for e.g. an element to communicate with one of a plurality of devices and/or ports (and likewise for ports and devices). Also, the facilitating means may pose restrictions to how may e.g. elements can communicate with a given port or device. In this manner, the facilitating means will define which elements, ports, and/or ports may communicate. Thus, an element CAN communicate (determined by the facilitating means) with e.g. multiple ports but communicates only with one of those ports—due to the operation of the facilitating means.

In addition, preferably the means for operating the identifying and facilitating means with n4 being a value lower than n3 are adapted to set up a second configuration having each of the n4 ports operable and wherein the facilitating means facilitate that:

each of a first number, n9<n6, of the n4 ports communicate with at least one element being adapted to communicate with a plurality of the n4 ports and

each of a second number, n10>n7, of the n4 ports communicate with a plurality of elements, which communicate with only that of the n4 ports.

Especially when combining these two configurations in the same system is it seen that when more ports (for the lower port count configuration) each communicates with multiple elements communicating only, due to the facilitating means, with that port, the redundancy for each of those ports is increased. This increases the probability that this lower port count configuration will work even when the number of defect or non-functional elements increases.

A fourth aspect of the invention relates to a system comprising:

a data bus,

a first number, n1, of devices adapted to interchange data on the data bus,

a second number, n2, of elements each adapted to communicate with one of the devices,

a third number, n3, of input/output ports each adapted to communicate with one or more external computers or networks and to communicate with one of the second number of elements, n3<n2,

means for identifying which of the elements are functional,

means for determining which of a number of predetermined sets of ports may communicate with the bus via the functional elements,

first means for facilitating communication between pairs of one of the functional elements and one of the n1 devices, and

second means for facilitating communication between pairs of one of the functional elements and one of the I/O ports of the determined set of ports.

Again, as is described above, different sets of predetermined groups of ports may be tested—normally from a higher number of ports to lower numbers of ports—in order to determine a configuration (set of ports) which is operative. As mentioned above, the ports of the sets and a positioning thereof in the system may be important parameters when determining the sets.

This testing or configuration of the system may be fully on-chip so that, upon power up of the chip, the testing and configuration is automatic. Thus, when testing the chip, a configuration (normally that possible with the highest port count) is selected and tested by e.g. an external tester.

A fifth aspect of the invention relates to a system having

a number, n2, of elements adapted to communicate with each other, such as via a data bus,

a number, n3, of input/output ports each adapted to communicate with one or more external computers or networks and to communicate with one of the number of elements, n3≦n2,

means for facilitating communication between pairs of one of the elements and one of the I/O ports,

means for defining:

i. a first configuration having each of a first number, n5≦n3, of the ports operable and wherein the facilitating means facilitate that:

1. each of a first number, n6, of the n5 ports can communicate with at least one element which can communicate with a plurality of the n5 ports and

2. each of a second number, n7, of the n5 ports can communicate with a plurality of elements which can communicate with only that of the n5 ports, and

ii. a second configuration having each of a second number, n8<n5, of the ports operable and wherein the facilitating means facilitate that:

1. each of a first number, n9<n6, of the n8 ports can communicate with at least one element which can communicate with a plurality of the n8 ports and

2. each of a second number, n10>n7, of the n8 ports can communicate with a plurality of elements which can communicate with only that of the n8 ports.

As already mentioned above, the combination of these two configurations will increase the probability that the second configuration will be operable if the first, most desired one (higher port count) does not.

In this embodiment, elements and the ports may be positioned in an at least substantially two-dimensional area of the system, where the ports are distributed along a perimeter of the area, where the n7 ports have predetermined positions along the perimeter of the area, and where the n8 elements each is adapted to communicate with at least one of the n3 ports.

In this connection, “at least substantially two-dimensional” will mean that a given thickness will be tolerated. The present system is normally defined as a single chip or an assembly of chips—and the important parameter is the relevant positions of the elements, ports etc in a two-dimensional plane due to the electrical/optical routing between the ports/elements/devices.

A sixth, seventh, and eight aspect of the invention are more back-end-related and relate to methods of ensuring an easier timing of signals from or to the system. When using redundant elements and/or different configurations, it may not be clear which element communicates with a given port. Thus, these aspects alleviate the timing problems occurring on that behalf.

The sixth aspect relates to a system comprising

a number, n2, of elements adapted to communicate with each other, such as via a data bus,

a number, n3, of input/output ports each adapted to communicate with one or more external computers or networks and to communicate with one of the number of elements, and

a plurality of means each communicatively connected to a plurality of elements and a respective port and being adapted to facilitate communication between one of the respective elements and the respective I/O port,

where the facilitating means comprise:

means for selecting one of the plurality of respective elements communicatively connected thereto and for receiving data there from,

means for receiving a clocking signal from the respective one of the plurality of elements communicatively connected thereto, and

means for outputting the received data to the port in accordance with the clocking signal received.

The seventh aspect relates to a system comprising

a number, n2, of elements adapted to communicate with each other,

a number, n3, of input/output ports each adapted to communicate with one or more external computers or networks and to communicate with one of the number of elements, and

a plurality of means each communicatively connected to a plurality of elements and a respective port and being adapted to facilitate communication between one of the respective elements and the respective I/O port,

where the facilitating means comprise:

means for selecting one of the plurality of respective elements communicatively connected thereto and for receiving data there from,

means for receiving a clocking signal from the port and transmitting the clocking signal to the selected one of the plurality of respective elements, and

means for outputting the received data to the port in accordance with the clocking signal transmitted.

The eighth aspect relates to a system comprising

a number, n2, of elements adapted to communicate with each other,

a number, n3, of input/output ports each adapted to communicate with one or more external computers or networks and to communicate with one of the number of elements, and

a plurality of means each communicatively connected to a plurality of ports and a respective element and being adapted to facilitate communication between one of the respective elements and the respective I/O port,

where the facilitating means comprise:

means for selecting one of the plurality of respective ports communicatively connected thereto and for receiving data there from,

means for receiving a clocking signal from the respective one of the plurality of ports communicatively connected thereto, and

means for outputting the received clocking signal to the element as well as the received data in accordance with the clocking signal.

In each of these three aspects, both the source of data and clock is selected, whereby timing is much easier.

The means for outputting the data may be any means adapted to retime or re-synchronize a signal, such as a register, or a FIFO.

Also, an I/O port preferably comprises one or more pads adapted to be electrically contacted by surrounding electronics. Such electronics may be computers or networks but are normally contacted via a package in which the system is positioned (when shaped as a single chip of multiple chips) and where the pads are bonded to electrical conductors of the package.

A ninth aspect of the invention relates to how to “turn off” elements or other blocks which are not fully functional or which are not desired to operate. This aspect relates to a system comprising

a number, n2, of elements adapted to communicate with each other, such as via a data bus,

a number, n3, of input/output ports each adapted to communicate with one or more external computers or networks and to communicate with one of the number of elements,

a plurality of means each communicatively connected to a plurality of elements and a respective port and being adapted to facilitate communication between pairs of one of the elements and one of the I/O ports,

means for providing power and a clocking signal to each element, and

means for removing the clocking signal to one or more elements in order to render the element(s) non-functional.

Thus, instead of removing power from the elements, the clock is simply taken away from the elements.

Preferably, the system comprises CMOS or domino logic elements.

In any of the above aspects, the identifying means may be adapted to perform the identification on the basis of a result of a self-test of each of the elements. The determination of which elements are to be used may be based on which elements are actually functional and how many—and which—are needed. It should be remembered that even a few elements not functioning at strategic places might render a given configuration impossible—even though a sufficient number of elements is actually operable. This is defined by the laying out of the elements etc and on the facilitating means.

In this situation, the identifying means may comprise testing means operationally connected to each element for receiving the self-test result of the elements and for outputting the results of the self-tests.

Then, the system may further comprise central means for receiving the results output and for generating and outputting information for the first and/or second facilitating means.

In addition or alternatively, one testing means may be provided for each element and for receiving the self-test result from the element and output the self-test result. Then, in one embodiment:

one or more of the testing means further comprise means for receiving a self-test result output from another testing means, combining the received self-test result with that received from the pertaining element, and to output the combined test result, and

the first and/or second facilitating means are adapted to receive the test result from a testing means and to operate accordingly.

In any of the above aspects, preferably each of the first facilitating means is adapted to provide communication between an element and one of two or more predetermined devices.

In any of the above aspects, n2 may be larger than n1, and n1 may be equal to n3.

In general: each of the second facilitating means is preferably adapted to provide communication between an element and one of two or more predetermined devices.

Also, preferably at least one device is adapted to operate in one of two modes, where one mode is a mode where it is adapted to receive data from (and relay it to the pertaining element) and transmit data (from the pertaining element) to the data bus and the other mode being one where data received from the data bus is relayed back to the data bus-without communicating it to or from the pertaining element. Then, each of the first facilitating means may facilitate communication between one device and one element.

In one embodiment, the second facilitating means are interconnected in a daisy chain manner, and where at least part of the second facilitating means are adapted to operate in one of two modes being:

one mode where communication is facilitated between a respective I/O port and an element and

another mode where communication is facilitated between the respective I/O port and a neighbouring, second facilitating means on the daisy chain while communication is facilitated between the respective element and another neighbouring, second facilitating means on the daisy chain.

Also, it may be desired that the first facilitating means are interconnected in a daisy chain manner, and where at least part of the first facilitating means are adapted to operate in one of two modes being:

one mode where communication is facilitated between a respective I/O port and an element and

another mode where communication is facilitated between the respective I/O port and a neighbouring, first facilitating means on the daisy chain while communication is facilitated between the respective element and another neighbouring, first facilitating means on the daisy chain.

In the presently preferred embodiment, the data bus is a ring bus.

It is clear that the larger a functional block on, e.g. a chip, is, the larger the probability of failure. Thus, it is preferred that the elements of the system have as much logic, functionality, or storage as possible in that this will provide redundancy of this logic/functionality/storage. The actual logic/functionality/storage required/desired in the elements will, naturally, depend on the actual functionality of the system.

Examples are elements being adapted to:

perform a look-up operation on the basis of at least part of a packet or frame received from an I/O port and to forward at least part of the packet or frame received to a device,

perform packet or frame processing on a packet or frame received from an I/O port,

store a packet or frame received from an I/O port before transmission of at least part of the packet or frame to a device.

Preferably, the system is prepared as a single chip. In this situation, it is desired that the size of the individual elements on the chip are much larger than that of the individual ports/means/devices. It is desired that all or most of the parts of the communication path (being specific for that path) between a port and a device, that are not directly related to the facilitating means and the interface to the pins of the chip and the data bus, be introduced into the elements and thereby be provided in a redundancy. This also includes any storage or buffers in that path. Thus, preferably, an area, on an IC die, of an element is preferably at least 4 times, such as at least 6 times, preferably at least 8 times, such as at least 10 times the combined area of a device, a port, a first facilitating means, and a second facilitating means.

Preferably, the means further comprises means for disabling one or more of the n2 elements, which do not form part of the n3 elements. Then, the system may comprise means for providing power to the one or more elements and wherein the disabling means comprise means for cutting off the power to the one or more elements. In addition or alternatively, the system may comprise means for providing a clocking signal to the one or more elements and wherein the disabling means comprise means for cutting off the clocking signal to the one or more elements.

An interesting aspect of the invention is a system for configuring a system according to any of the above aspects, the system further comprising:

means for determining whether n3 elements are functional,

means for, if so, for each of the n3 functional elements, having the first and second facilitating means facilitate communication between the actual element and a device and between the actual element and an I/O port, respectively,

means for, if not, providing information to the effect that the system is defect.

In that aspect, the system may further comprise means for disabling one or more of the n2 elements not forming part of the n3 elements.

Respective to the first aspect, the invention relates to a tenth aspect relating to a method of operating a system for communicating between a number of elements via a data bus, the system comprising:

a data bus,

a first number, n1, of devices adapted to interchange data on the data bus,

a second number, n2, of elements each adapted to communicate with one of the devices, n1≦n2, and

a third number, n3, of input/output ports each adapted to communicate with one or more external computers or networks and to communicate with one of the second number of elements, n3<n2,

the method comprising:

identifying n3 of the elements which are to be used,

facilitating communication between pairs of one of the n3 elements and one of the n1 devices, and

facilitating communication between pairs of one of the n3 elements and one of the n3 I/O ports.

Respective to the second embodiment, an eleventh aspect of the invention relates to a method of operating a system for communicating between a number of elements via a data bus, the system comprising:

a data bus,

a first number, n1, of devices adapted to interchange data on the data bus by, repeatedly, a plurality of the devices forwarding data simultaneously to a next device on the data bus,

a second number, n2, of elements each adapted to communicate with one of the devices, n1≦n2,

a number, n3, of input/output ports each adapted to communicate with one or more external computers or networks and to communicate with one of the second number of elements,

wherein a number of the n1 devices comprises:

means for delaying data received from the data bus before transmission thereof on the bus, and

means for circumventing the delaying means,

the method comprising:

identifying n4<n1 of the elements which are to be used,

facilitating communication between n4 pairs of one of the n4 elements and one of the n1 devices, and

having the circumventing means circumvent the delaying means in those of the n1 devices not forming part of the n4 pairs.

The method of the eleventh aspect may further comprise the steps of:

selecting one or more data packets to be switched, each data packet being held by a respective device, and

repeatedly, a first number of times:

forwarding, at least substantially simultaneously, at least part of each of the data packets and pertaining receiving device information to a next device along the interconnecting means,

receiving, at least substantially simultaneously and from the interconnecting means, the at least part of the selected data packets and the pertaining receiving device information, and

determining, at least substantially simultaneously in each device having received at least part of a data packet, on the basis of the pertaining receiving device information, whether the at least part of the data packet is intended for the device and, if so, storing a copy of the at least part of the data packet in the device.

Referring to the third aspect, the invention relates to a twelfth aspect relating to a method of testing a system comprising:

a data bus,

a first number, n1, of devices adapted to interchange data on the data bus,

a second number, n2, of elements each adapted to communicate with one of the devices,

a third number, n3, of input/output ports each adapted to communicate with one or more external computers or networks and to communicate with one of the second number of elements, n3<n2,

means for identifying n4 of the elements which are to be used,

first means for facilitating communication between pairs of one of the n4 elements and one of the n1 devices, and

second means for facilitating communication between pairs of one of the n4 elements and one of the n3 I/O ports, the method comprising:

providing power to the system,

operating the identifying and facilitating means with n4=n3,

determining whether communication is possible from each of the n3 ports to the data bus in the powered system, and

if not, operating the identifying and facilitating means with n4 being a value lower than n3.

In this relation, the step of, if not, operating the identifying and facilitating means with n4 being a value lower than n3 may comprise operating the identifying and facilitating means with n4 being one value of a predetermined set of values each being lower than n3.

Also, the elements and the ports may be positioned in an at least substantially two-dimensional area of the system, the ports may be distributed along a perimeter of the area, the sets may be defined as sets of ports having predetermined positions along the perimeter of the area, and the identifying step may comprise identifying n4 functional elements each being adapted to communicate with at least one of the ports of the set.

In this situation, the identifying step may comprise identifying n4 functional elements each communicating, via the second facilitating means, with only one of the ports of the set.

Also, in this aspect, the step of operating the identifying and facilitating means with n4=n3 preferably comprises setting up a first configuration of the system having each of the n3 ports operable and wherein the facilitating means facilitate that:

each of a first number, n6, of the n3 ports can communicate with at least one element which can communicate with a plurality of the n5 ports and

each of a second number, n7, of the n3 ports can communicate with a plurality of elements, which can communicate with only that of the n3 ports.

Also, preferably, the step of operating the identifying and facilitating means with n4 being value lower than n3 comprises setting up a second configuration having each of the n4 orts operable and wherein the facilitating means facilitate that:

each of a first number, n9<n6, of the n4 ports can communicate with at least one element which can communicate with a plurality of the n4 ports and

each of a second number, n10>n7, of the n4 ports can communicate with a plurality of elements, which can communicate with only that of the n4 ports.

A thirteenth aspect relates to a method of operating a system comprising:

a data bus,

a first number, n1, of devices adapted to interchange data on the data bus,

a second number, n2, of elements each adapted to communicate with one of the devices,

a third number, n3, of input/output ports each adapted to communicate with one or more external computers or networks and to communicate with one of the second number of elements, n3<n2,

the method comprising:

identifying which of the elements are functional,

determining which of a number of predetermined sets of ports may communicate with the bus via the functional elements,

facilitating communication between pairs of one of the functional elements and one of the n1 devices, and

facilitating communication between pairs of one of the functional elements and one of the I/O ports of the determined set of ports.

A fourteenth aspect relates to method for operating a system having

a number, n2, of elements adapted to communicate with each other, such as via a data bus,

a number, n3, of input/output ports each adapted to communicate with one or more external computers or networks and to communicate with one of the number of elements, n3≦n2,

means for facilitating communication between pairs of one of the elements and one of the I/O ports,

the method comprising:

defining:

i. a first configuration having each of a first number, n5≦n3, of the ports operable and wherein the facilitating means facilitate that:

1. each of a first number, n6, of the n5 ports can communicate with at least one element which can communicate with a plurality of the n5 ports and

2. each of a second number, n7, of the n5 ports can communicate with a plurality of elements which can communicate with only that of the n5 ports, and

ii. a second configuration having each of a second number, n8≦n5, of the ports operable and wherein the facilitating means facilitate that:

1. each of a first number, n9<n6, of the n8 ports can communicate with at least one element which can communicate with a plurality of the n8 ports and

2. each of a second number, n10>n7, of the n8 ports can communicate with a plurality of elements which can communicate with only that of the n8 ports.

In this aspect, the elements and the ports are preferably positioned in an at least substantially two-dimensional area of the system, where the ports are distributed along a perimeter of the area, where the n7 ports have predetermined positions along the perimeter of the area, and where the method comprises the step of the n8 elements each communicating with at least one of the n3 ports.

A fifteenth, sixteenth, and seventeenth aspect relates, as the sixth to ninth aspects, to backend/timing relates aspects. The sixteenth aspect relates to a method of operating a system comprising

a number, n2, of elements adapted to communicate with each other,

a number, n3, of input/output ports each adapted to communicate with one or more external computers or networks and to communicate with one of the number of elements, and

a plurality of means each communicatively connected to a plurality of elements and a respective port and being adapted to facilitate communication between one of the respective elements and the respective I/O port,

the method comprising the steps of the facilitating means:

selecting one of the plurality of respective elements communicatively connected thereto and for receiving data there from,

receiving a clocking signal from the respective one of the plurality of elements communicatively connected thereto, and

outputting the received data to the port in accordance with the clocking signal received.

The sixteenth aspect relates to method of operating a system comprising:

a number, n2, of elements adapted to communicate with each other,

a number, n3, of input/output ports each adapted to communicate with one or more external computers or networks and to communicate with one of the number of elements, and

a plurality of means each communicatively connected to a plurality of elements and a respective port and being adapted to facilitate communication between one of the respective elements and the respective I/O port,

the method comprising the steps of the facilitating means:

selecting one of the plurality of respective elements communicatively connected thereto and for receiving data there from,

receiving a clocking signal from the port and transmitting the clocking signal to the one of the plurality of respective elements, and

outputting the received data to the port in accordance with the clocking signal transmitted.

The seventeenth aspect relates to a method of operating a system comprising

a number, n2, of elements adapted to communicate with each other,

a number, n3, of input/output ports each adapted to communicate with one or more external computers or networks and to communicate with one of the number of elements, and

a plurality of means each communicatively connected to a plurality of ports and a respective element and being adapted to facilitate communication between one of the respective elements and the respective I/O port,

the method comprising the facilitating means:

selecting one of the plurality of respective ports communicatively connected thereto and for receiving data there from,

receiving a clocking signal from the respective one of the plurality of ports communicatively connected thereto, and

outputting the received clocking signal to the element as well as the received data in accordance with the clocking signal.

Respective to the ninth aspect, an eighteenth aspect relates to a method of operating a system comprising

a number, n2, of elements adapted to communicate with each other, such as via a data bus,

a number, n3, of input/output ports each adapted to communicate with one or more external computers or networks and to communicate with one of the number of elements,

a plurality of means each communicatively connected to a plurality of elements and a respective port and being adapted to facilitate communication between pairs of one of the elements and one of the I/O ports,

the method comprising:

providing power and a clocking signal to each element, and

removing the clocking signal to one or more elements in order to render the element(s) non-functional.

Again, in general, the identifying step preferably comprises performing the identification on the basis of a result of a self-test of each of the elements. Then, the identifying step may comprise testing means operationally connected to each element receiving the self-test result of the elements and for outputting the results of the self-tests. In one embodiment, the system has a central means receiving the results output and generating and outputting information for the first and/or second facilitating means. In another embodiment, one testing means is provided for each element receives the self-test result from the element and outputs the self-test result. In that embodiment:

one or more of the testing means could further receive a self-test result output from another testing means, combine the received self-test result with that received from the pertaining element, and output the combined test result, and

the first and/or second facilitating means could receive the test result from a testing means and operate accordingly.

Preferably, each of the first facilitating means provides communication between an element and one of two or more predetermined devices.

Also, preferably, each of the second facilitating means provides communication between an element and one of two or more predetermined devices.

In one embodiment, n2=n1 and at least one device operates in one of two modes, where one mode is a mode where it is adapted to receive data from (and relay it to the pertaining element) and transmit data (from the pertaining element) to the data bus and the other mode being one where data received from the data bus is relayed back to the data bus without communication to or from the pertaining element. In that situation, each of the first facilitating means preferably facilitates communication between one device and one element.

In general, it is preferred that the second facilitating means are interconnected in a daisy chain manner, and where at least part of the second facilitating means operates in one of two modes being:

one mode where communication is facilitated between a respective I/O port and an element and

another mode where communication is facilitated between the respective I/O port and a neighbouring, second facilitating means on the daisy chain while communication is facilitated between the respective element and another neighbouring, second facilitating means on the daisy chain.

Also, preferably, the first facilitating means are interconnected in a daisy chain manner, and where at least part of the first facilitating means operates in one of two modes being:

one mode where communication is facilitated between a respective I/O port and an element and

another mode where communication is facilitated between the respective I/O port and a neighbouring, first facilitating means on the daisy chain while communication is facilitated between the respective element and another neighbouring, first facilitating means on the daisy chain.

In addition, normally at least one of the elements:

performs a look-up operation on the basis of at least part of a packet or frame received from an I/O port and to forward at least part of the packet or frame received to a device,

performs packet or frame processing on a packet or frame received from an I/O port,

stores a packet or frame received from an I/O port before transmission of at least part of the packet or frame to a device.

In one embodiment, the system further comprises the step of disabling one or more of the n2 elements, which do not form part of the n3 elements. In one situation, the method comprises the steps of providing power to the one or more elements and cutting off the power to the one or more elements. In another situation, the method comprises the steps of providing a clocking signal to the one or more elements and cutting off the clocking signal to the one or more elements.

An interesting aspect is that relating to a method for configuring a system according to any of the tenth to eighteenth aspects, the method further comprising:

determining whether n3 elements are functional,

if so, for each of the n3 functional elements, having the first and second facilitating means facilitate communication between the actual element and a device and between the actual element and an I/O port, respectively,

if not, providing information to the effect that the system is defect.

That method may further comprise disabling one or more of the n2 elements not forming part of the n3 elements.

In the following, preferred embodiments of the invention is illustrated with reference to the drawing wherein:

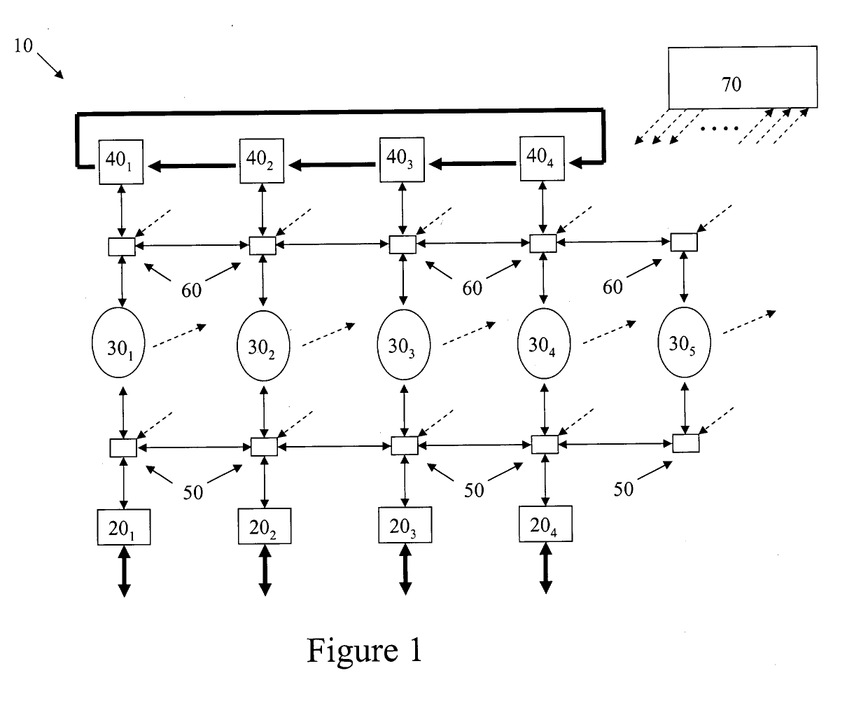

FIG. 1 illustrates a box diagram of the primary elements of the system of a first preferred embodiment,

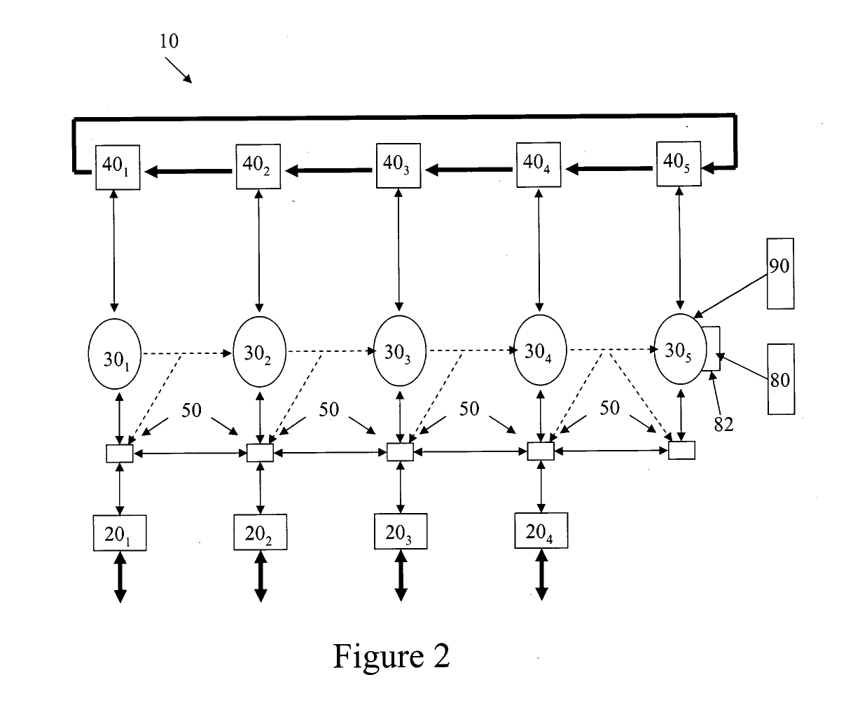

FIG. 2 illustrates a box diagram of the primary elements of a second preferred embodiment,

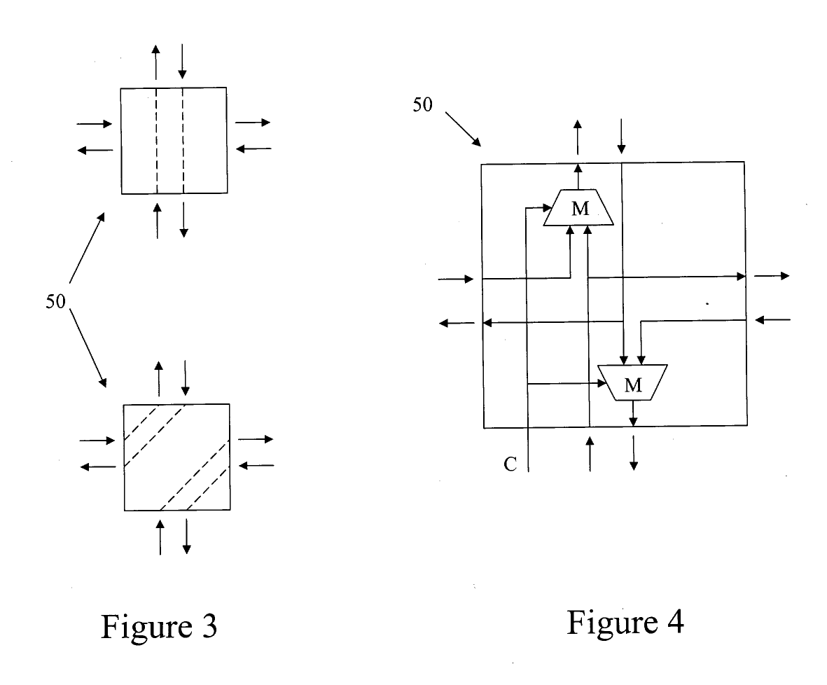

FIG. 3 illustrates two modes of facilitating/selecting means for use in the preferred embodiments of the system,

FIG. 4 illustrates a more detailed embodiment of a facilitating/selecting means,

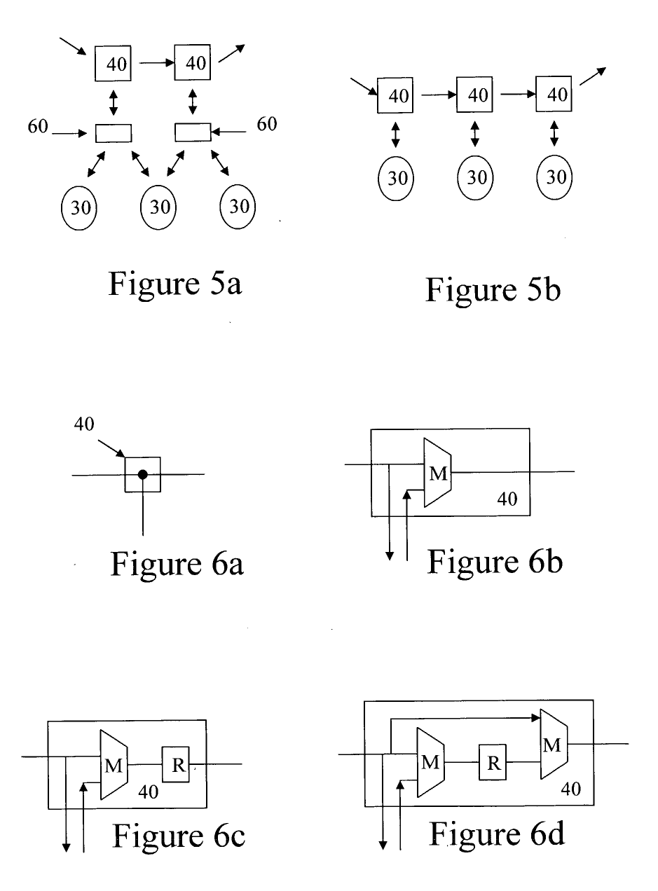

FIG. 5 illustrates two different uses of devices 40,

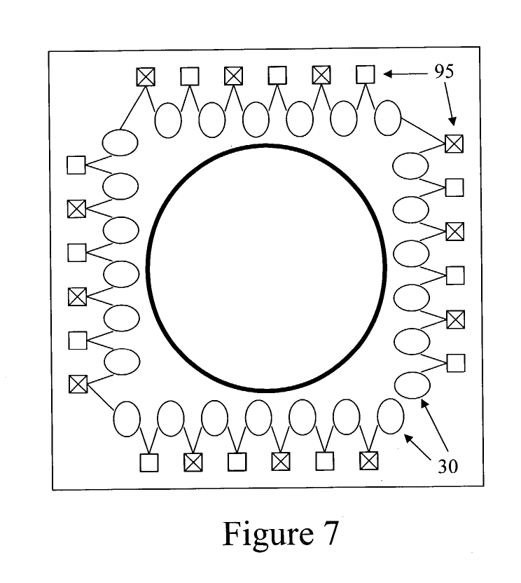

FIG. 6 illustrates four different embodiments of devices 40,

FIG. 7 illustrates reducing functionality of a chip with redundancy, and

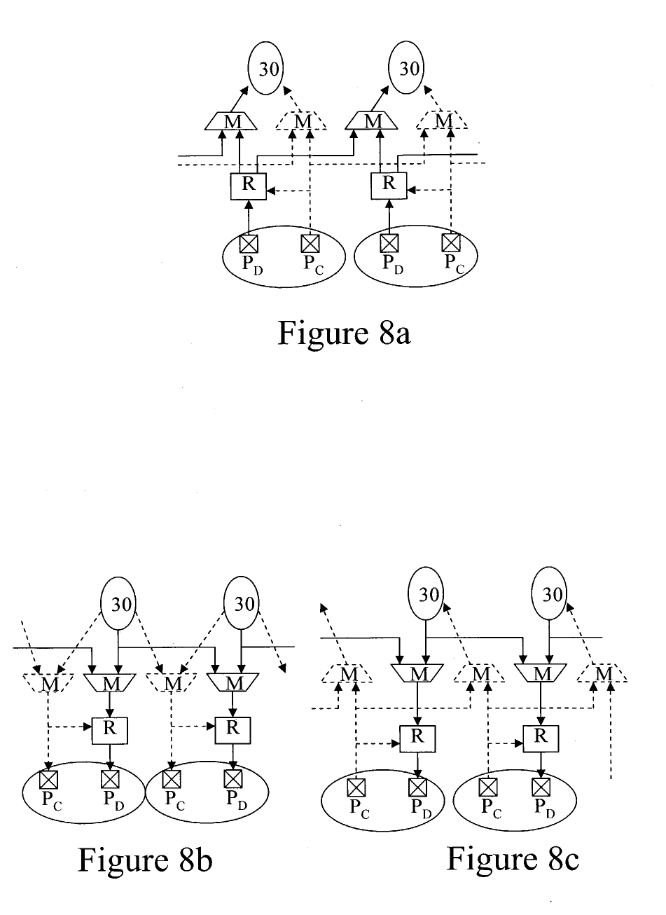

FIG. 8 illustrates the use of a register close to the pad of a chip.

Embodiment 1

In FIG. 1, a switch 10 is illustrated wherein four ports, 20₁, 20₂, 20₃, and 20₄ exchange data with outside network(s) via the fat double arrows extending away there from. The ports 20 exchange data between themselves via four devices 40₁, 40₂, 40₃, and 40₄ exchanging data via a one way circular data bus illustrated by the fat single arrows. The actual manner of exchange of data on the bus may be seen from U.S. patent application No. 60/287,718 which is hereby incorporated by reference. This manner additionally requires a Look-Up engine and an arbiter as well as means for transporting data packet header data from the ports to the LU engine and switching headers from the arbiter to the ports. These elements are not illustrated in that they are not relevant to the understanding of the present invention. The full operation thereof, however, may be learned from the above application.

Between the receipt of data in a port 20 and the transmission thereof on the bus, a number of actions will be performed on the data. Such actions will be the checking of the integrity of the data, the analysis thereof in order to determine from which port 20 the data should be output, etc. These actions are performed by the elements 30 in the present embodiment. In this embodiment, these actions will depend only on the nature and contents of the data received and not on which of the elements 30 performs them.

The present embodiment 10 may be a single switch chip—an Ethernet switch. Due to the fact that the MAC layer functions are performed in the elements 30, the ports 20 will be simple and take up very little space on the switch chip. Also, the devices 40 are only required to receive data cells to be transmitted (including a header informing a receiving device whether the data packet is to be copied to the pertaining element 30 or simply relayed to the next device 40), transmit these and relay and analyse cells and headers received from the earlier device on the data ring. Thus, also the devices will take up little space on the chip.

Contrary to that, the elements 30 are quite complex elements that will take up more space on the chip. Therefore, it is quite likely that any error in the chip will result in the malfunctioning of an element 30. Therefore, an additional element 30 is introduced as a redundant element for use if one of the other elements malfunctions or is flawed during manufacture.

However, in this manner, one or more ports 20 must be able to communicate with more than one element 30, and one or more devices 40 should be able to communicate with more than one element 30. In the present embodiment, all but one element 30 are adapted to communicate with one of two predetermined ports 20 and one of two predetermined devices 40. The selection between the two ports 20 takes place via a first selecting means 50 of which one is provided for each element 30. Similarly, the selection between the two devices 40 takes place via a second selecting means 60 of which one is provided for each element 30.

In this manner, a malfunction in any one of the elements 30 may be worked around and data from any receiving port 20 may be routed via a functioning element 30, a device 40, the ring bus, another device 40, another element 30 and to the correct outputting port 20.

In the present embodiment, a Built In Self Test is performed in order to identify any malfunctioning elements 30 and to operate the selecting means 50 and 60 so as to route past any such malfunctioning element 30. This BIST is controlled by an element 70, which receives (dashed arrows) the self-test results from each element 30 and subsequently instructs the means 50 and 60 accordingly. Naturally, the element 70 may be on-chip or off-chip.

The functioning of the means 50 and 60 will be described further below

If more than a single element 30 fails, the present embodiment will not be able to fix the problem—and the chip could be discarded due to the fact that ports thereof will not function. However, any number of redundant elements 30 (and corresponding means 50 and 60) may be provided if it is determined that the probability of more than a single element fails is problematic. Also, as will be described further below, such chips or dies may be used in other products having a lower number of ports.

Embodiment 2

FIG. 2 illustrates an alternative embodiment to that of FIG. 1.

The largest differences between the embodiments of FIGS. 1 and 2 are the fact that, now:

an additional device, 405, is present on the ring,

the means 60 are not present in FIG. 2, and

the element 70 is not present, whereby the conveying of the self-test results and the controlling of the elements 50 is performed in a different manner.

In FIG. 2, one device 40 is provided for each element 30. In that manner, the means 60 of FIG. 1 may be avoided. However, a different functionality of the devices 40 will be required. In order for the arbiter etc. of the switch to be the same (corresponding to the number of ports 20), one of the devices 40 is rendered “invisible” during operation. This device corresponds to the defective or redundant element 30.

The “invisible” device will thus not present information on the ring and will only relay information received to the next device. This relaying may take one or a few clock cycles and thereby delay the circulation of information. Invisibility will be described further below.

The communication of test results from the elements 30 and the controlling of the means 50 may be performed so that (see the dashed arrows) each element 30 relays its result (such as, how many elements—including the element itself—to the left thereof are defect) to the next element 30 and controls its pertaining means 50 accordingly. One could envision that the vertical connection between element 30 and means 50 is the default connection and the horizontal one is the redundant connection. The means 30 will then inform the element 30 to the right thereof whether to take its default connection (no defect elements 30 to the left thereof) or the redundant connection (one or more defect elements 30 to the left thereof). Alternatively, the elements 30 may report their results directly to the means 50 which then forward the results to the right in FIG. 2.

Subsequent to this configuration, a simple standard test will be able to determine whether all ports 20 are active or if one is inactive (due to more than one element 30 being defect).

In relation to FIGS. 1 and 2, it should be noted that the aspects relating to the control information flow (the use of the element 70 or the daisy chain manner of information flow) and the use of the additional device 405 are independent on each other.

Bus Types and Invisibility on the Bus

In general, the type of bus over which the elements 30 communicate will not, for a number of applications and embodiments, be critical. Embodiments 1 and 2 both use a systolic one-way ring bus, but any other type of bus, such as a two-way ring bus or a normal linear bus, could be used. Naturally, a corresponding altering of the manner of communication over the bus would be required.

FIGS. 5a and 5b recapitulate the two overall structures of embodiments 1 and 2, either having a lower number of attachment points on the bus (FIG. 5a) where elements 30 will then be adapted to communicate with multiple devices (40) or where each element 30 communicates with one device 40 (FIG. 5b).

In general, when redundant elements are used, the attachment point between the bus and an element may either be transparent (with or without a delay of data transmission) or each attachment point may communicate with multiple elements.

A number of manners exist of communicating over a bus. One manner being a simple one where all elements simply receive all information transmitted at the same time. In this manner, a non-functioning or redundant element will not interfere with the data transmission (as long as it does not—due to a malfunction—actually harm the bus). In this situation, the attachment points may be transparent causing no delay. This is illustrated by FIG. 6a, illustrating a device 40, where all elements receive the same information and where only a single element 30 may transmit data at any time. In general, signal propagation in chips will depend on the distance between transmitter and receiver. The longer the distance, the lower the frequency with which the communication can occur.

Other busses have repeaters, which then require a one-way direction of the data on the bus—and causing a slower data transmission frequency thereof—when the distance between transmitter and receiver is fixed. Again, other busses have clock delays, which also require one-way traffic, facilitate a higher data transmission frequency, but requiring a systolic behaviour of the data transmission. This will be described next.

However, if the data transmitted on the bus is received, analysed, copied to the element and/or relayed to another element, the operation of these steps and any delay caused thereby may be problematic.

The most difficult bus type to manage is a systolic ring bus where multiple pieces of data are transmitted at the same time and where the interconnection between the bus and an element will cause e.g. a delay.

In this respect, FIG. 6b illustrates a bus structure where each device 40 comprises a MUX (M) which is controlled to either forward the information/data received from the left part of the bus or information from the bottom (from the element 30). Also, the device 40 may derive information from the bus before the MUX. This bus needs not be clocked, although this may increase (e.g. double) the max path between clocked devices and hence reduce the throughput of the bus proportionally, whereby information flows from left to right. The operation of the MUX M is that it controls the information to the right of the MUX M. If the bus is not a ring bus, information flows from one end to the other. If the bus is a ring bus, information may be spread to all devices 40. Various schemes for determining an order of communication on the bus are known, such as token passing.

FIG. 6c illustrates an alternative embodiment where the device 40 comprises both a MUX having the function as that in FIG. 6b but where the output of the MUX enters a register R where the data/information is delayed for e.g. one clock cycle. This bus is clocked. One manner would be to have the same single piece of information/data traversing the bus (linear or ring bus) as a function of the clocking. Another manner is to have it systolic where multiple pieces of information/data are passed at the same time in a systolic manner. This manner is described in the above-mentioned patent application.

In FIG. 6d, the embodiment of FIG. 6c has been added another MUX M, which may be used for rendering an element 30 connected to the device 40 invisible in the sense that the device 40 may remove any influence the element 30 might have on the information on the bus. On the bus, when the last MUX M circumvents the first MUX M and the register R, the only influence of the device 40 is a small time delay experienced by the data when traversing through the second MUX M.

In this manner, the device 40 of FIG. 6d may be used in both embodiments illustrated in FIGS. 5a and 5b, whereas the embodiments illustrated in FIGS. 6a-6c are optimal only as illustrated in FIG. 5a in that they cannot be made invisible. Not rendering a device invisible may either disturb the data transmission on the bus (when the device or the pertaining element 30 is defective) or reduce the bandwidth on the bus (FIG. 6c) in that the clock delay at the register will add to the total delay on the bus.

Binning

An interesting aspect in the use of the routing, muxes, etc used for controlling the selection of redundant elements is the fact that the same functionality may be used for configuring a chip to also other configurations. If a chip has too many errors to be able to—in spite of the redundancy—function as planned, the chip may be configured to a reduced functionality.

If the chip was e.g. a 24 port switch chip (see FIG. 7) having 24 ports 95 and 25 elements 30 (where one element is redundant), this chip could, if more than a single element 30 was defect, be configured to be e.g. a 12 port switch chip by rendering 12 of the 24 ports ineffective—such as by a bonding option. Normally, the busses and arbiter, and a LU-engine would be sized after the highest functionality—whereby this lower functionality should give no problems.

There are many ways of selecting the 12 operative ports. However, it is important to ensure that the bonding option selected is as widely applicable as possible, that is, that it will render the chip useful in as many defect scenarios as possible. Also, it is desired to have only a single bonding option.

One such bonding option may be seen from FIG. 7 where the crossed out ports are rendered non-functional—and where these ports will not be bonded to pins/balls on the final, packaged chip.

In this embodiment, every second port 95 is not used. In this manner, all but a single element 30 may potentially be used—and each port 95 is able to communicate with two elements 30. The only manner that this 12-port chip will not be functional will be one where two adjacent elements 30 communicating with the same port 95 are defective. Other than that, the chip will be functional with this reduced functionality.

To compare: if all ports along two of the four sides of the chip were rendered nonfunctional with this reduced functionality, any two defect elements 30 communicating with any of the operational ports 95 would render the chip useless.

Naturally, different configurations with different functionalities may be defined (e.g. a 24 port, a 16 port, a 12 port, a 8 port chip—depending on the number of (and the distribution of) defective elements 30).

In this manner, the chip may be configured at the optimum configuration and tested. If the chip fails, the semi-optimum configuration may be tested etc. until the chip passes a test or is discarded.

The actual configuration of the chip is preferably based on BIST's and logics that are identical for the elements (at least elements that are otherwise identical).

Numerous manners of obtaining this exist. One manner is that of FIG. 1 where the central means 70 performs the configuration. This means 70 will receive the test results and then be able to determine which of the configurations is possible.

Another manner builds on the embodiment of FIG. 2. In this embodiment, most of the elements 30 receive information as to which of “its” two elements 50 to communicate with. This embodiment may be combined with one where a bitmap is distributed to the elements 30, where each position in the bitmap corresponds to whether the corresponding element 30 is or is not to be operable.

From this information from the neighbouring element 30 and the bitmap, the element 30 or means 50 may, during a test/configuration, know whether to simply communicate (and thereby reserve) with any functional element 30/means 50 or whether one thereof is reserved—and the other should be chosen.

In certain situations, it might be desirable, subsequent to the first configuration and testing, to pack the system into a packet having fixed potentials on a number of legs of the system whereby the systems configuration is defined fixedly thereafter. This is desired in situations where elements of the system may function at some points in time and not at other points in time. In that situation, the system may be tricked into believing that it has another configuration—a configuration not supported by e.g. the packet or bond-out. Also, such fixed-potential legs may be used for signalling to software what the configuration is supposed to be.

If the test information (see FIG. 2) is always forwarded, any bit map may be used in order to “down scale” the original functionality—while maintaining the simple test/configuration bit map described.

Cutting Off a Superfluous or Defect Element

In accordance with one aspect of the invention, the redundant or defect element 30 will be disabled by cutting off a clocking signal to the element 30. All elements 30 receive a clocking signal from a clocking signal provider 80, and between the provider 80 and each element 30, a cutting off element 82 (such as a transistor) is provided for cutting off the clocking signal. An alternative would be to cut off a power supply between a power supply 90 and the element 30 (each element naturally being supplied with power). This is illustrated for a single element 30 in FIG. 2.

In one situation, the element would be cut off by cutting off the power thereto. However, cutting off the power requires more transistors and is therefore more resource demanding.

Manners of Configuring and Testing the Present System

In general, at least three steps may be identified for testing and configuring the chip:

testing the chip and generating a type of e.g. vector—locating erroneous devices,

selecting which of the fully functioning devices to use (or determining e.g. bin sorting), and

configuring the individual devices:

The testing of the chip will, in a preferred embodiment, be a Built In Self Test performed by all elements. The present BIST may be any type of relevant testing of the elements 30. A Built In Logic Block Observation may be used where a predetermined input is provided to the element 30 and if the corresponding output corresponds to that expected, the BIST will be successful.

Alternatively or in addition, the BIST may comprise the inputting of data generated from noise—and where a signature is derived from the corresponding output of each element. This signature is then evaluated in order to determine whether the element passes or fails the test. The time during which this test is performed may be determined, varied or set in accordance with criteria—such as from the outside of the chip.

The selection may be performed at different points in time.

At the time of production, internal and/or external scan vectors may be fed to the elements in order to evaluate the resulting output thereof. Also, internal BIST's may be performed.

At a later point in time—such as when booting the chip, BIST's or external tests, such as controlled by software, may be performed.

Also, as will be described below, a voting may be used in order to determine which of the elements are functional.

The actual selection may also depend on the actual functionality of the chip. As will be described below, functional elements may be de-selected due to a given functionality and bond-out being desired.

A number of manners of configuring the chip (determining which elements are functional and which of those are to be used) are possible:

TTL (time to live):

central configuration:

local configuration with a central element:

local configuration:

Software configuration: it is determined which devices work

And this information is disseminated using one of the above methods to the devices.

TTL means that all devices are prepared to be 100% identical so that the addressing is altered in each element in order to reach the correct element. This may be obtained by counting down (information transmitted is transmitted to element No. x along the bus) or a bit shifting where a bit mask is transmitted with the information and where each intermediate element shifts the bit mask. The “final” element will, from the bitmap, be able to identify that the pertaining information is intended for that element. In that manner, the information arrives at the intended element and the bitmaps will define which elements are and are not active.

Central configuration means that a central unit knows which devices work. It may, e.g. receive the results of BIST's. This central unit distributes this knowledge and configures the devices on the basis of that knowledge.

Local configuration (within each element) may be performed in two manners: with or without a central element knowing which devices are operational. With this central element, the actual configuring may still be performed locally in the devices. If no such central element is used, each device is programmed to whether it is “in” or it is not. The device will then operate in one of two corresponding modes.

As to software-based configuration, three manners exist:

A BIST may be run after each power up or upon request from an operator—whereby the settings of the means 50 and 60 may be stored in software. In this manner, any elements 30 malfunctioning only at some points in time may be left out when malfunctioning (after testing again). Thus, a fully autonomous operation may be obtained.

Another manner of storing the settings of the means 50 and 60 would be to provide the setting in hardware—such as in an EPROM in the same chip or in another chip on the same board. In this manner, a new running of the BIST is not required after a power up of the system.

Finally, a fully software driven version is foreseen where the chip performs the BIST and setting up after each power up where the redundant/malfunctioning element(s) is/are identified and the facilitating means are operated after each power down. In this manner, the actual status of all elements is taken into account, whereby an occasionally weak element being weak at this moment may be circumvented now but maybe not later on where another element is weaker. Alternatively, software may be provided with each chip—defining which elements are operable.

The overall functioning of the selecting means may be seen from a combination of FIGS. 3 and 1 or 2. From FIGS. 1 and 2, it is clear (looking at e.g. the means 50 and starting from the left side) that for each element 30, which is functioning, the means 50 will combine the 30 port 20 and element 30 along a vertical axis. (See the upper part of FIG. 3). If one element malfunctions, the means 50 below the malfunctioning element 30 and any means 50 to the right thereof will now route information one step to the right (see the lower part of FIG. 3).

The same operation will be used with the means 60 of FIG. 1.

The selecting means may be made in a number of ways.

One way of providing the selecting means would be to provide laser/heat fusable multiplexers, which are laser/heat fused after a test of the individual devices. In this manner, a test is run a single time after manufacture and the operation of the selecting means would be fixed upon fusing. After that (after assembly of the chip), one has a functioning chip and one needs not occupy oneself with the malfunctioning element 30. Thus, a BIST is not required.

Another way of providing the selecting means would be to use means, which are settable by software/hardware. Such selecting means are illustrated in FIG. 4. This means has two multiplexers M, which are controllable by a control signal C.

Under all circumstances, the use of the preferred embodiment of the present invention facilitates the use of a simple hardware tester for use just after manufacture in that the result of the tester is a simple GO/NOGO. Normally, when testing hardware where individual parts may fail and the hardware still is acceptable, the tester needs to know which and how many parts may fail—and sort the tested hardware in groups of errors.

The present BIST and configuration is run before testing, whereby the tester will simply test whether the chip functions. Naturally, a register init, memory init etc may be performed before running the actual BIST, but the BIST and configuration of the chip is preferably run before the external chip tester is used. In addition, these inits may be performed both before and after the reconfiguration.

In addition, as described in relation to FIG. 7, the test and configuration of the chip—also where different configurations are possible—may be performed prior to the testing of the chip functionality on a chip tester. If the tester is able to either receive a signal describing which configuration the chip has—or if it is able to test each of the configurations possible—the chip may test and configure itself and the chip tester then ensure the functionality of the configuration chosen. If the chip tester is not able to receive the signal or test multiple configurations, multiple testers or multiple tests may be required.

An interesting aspect is one where the BIST has found that more than sufficient of the elements are functional—whereafter the configuration will select a suitable. number thereof. Then, an external test is run—and the chip is discarded due to the fact that one of the selected elements is now not—even though the opposite was indicated by the BIST—fully functional. In this situation, the chip may be re-configured to use another of the functional elements and then re-tested.

Voting

An interesting aspect of the testing and configuration of the chip is one where the results of the individual elements are compared. A majority decision may be made in order to determine which elements are operational and which are not. This has the advantage that even though multiple elements are defect—and maybe even providing the same, erroneous output, it is possible to isolate these.

Also, a combination may be made where, if it is difficult to determine which of the solutions output by defect and operable elements is the correct one, the testing performed of the elements may be prolonged or altered in order to facilitate the identification of the operable elements.

Backend/Timing Related Aspects of the System

Due to the redundancy, a single port/pad may be configured to communicate to or via one of two or more elements 30. Such elements may be driven with different clocks, whereby a timing issue arises. This is due to the fact that it is not possible from the outside of the chip to see which element one communicates with. That disadvantage is obviated by the present embodiment.

One manner of attacking that problem would be to provide a register R closer to the pad P than the e.g. MUX M. In that situation, the register may be clocked in a manner so that the signal on the pad is known—and always clocked by the same clock no matter which element 30 communicates with the register.

This is illustrated in FIG. 8, where FIG. 8a illustrates the ingress direction and FIGS. 8b, and 8c illustrate the egress direction.

In FIG. 8, a port is illustrated as two pads, a data pad PD and a clock pad Pc. Naturally, an actual port may have any number of data pads and any number of clock pads (however, normally only a single clock pad is used). In FIG. 8, data paths and MUX'es are drawn in full lines and clock paths and MUX'es are drawn in broken lines.

In FIG. 8a, the data from the data pad firstly enters a register R and is then routed to two MUX'es M. Each MUX M selects from which data pad/register the actual element 30 is to receive data. In addition, the clock enters at the clock pad and is fed to two clock MUX'es which also select the data pad corresponding to the data pad selected—for each element 30.

Each register is clocked by the data signal from the clock pad of the same port. Thus, the clocking of data into the chip is well defined and known to the outside of the chip.

In the egress direction illustrated in FIG. 8b, each port again has one or more (one illustrated) data pads and one or more (one illustrated) clock pads.

In this embodiment, the data from the elements 30 is fed to MUX'es M selecting from which element 30 the pertaining data pad is to receive data.

Each element 30 outputs a clocking signal to clock MUX'es M selecting the same element to feed the clock to the register R and the clock pad of the port. In that situation, the clocking of the data pad is defined by the element generating the data.

FIG. 8c illustrates an alternative where the element 30 actually receives a clock of a port, via a MUX M, the clocking of data on the data pad is actually controlled by the outside of the chip. Again, the clocking signal is fed to MUX'es M which, as the MUX'es multiplexing the data, selects the element 30 which is to communicate with the actual port.

Also, in one embodiment, the actual bus interconnecting the individual elements 30 or means 40 may be selected to be in a single clock domain. Thus, a clock transition is to take place (where the full chip is not to be in the same clock domain) between the bus and e.g. the elements 30. However, in a backend perspective, this is an easier method.

1. A system for communicating between a number of elements via a data bus, the system comprising:
a data bus,
a first number, n1, of devices adapted to interchange data on the data bus,
a second number, n2, of elements each adapted to communicate with one of the devices, n1<n2,
a third number, n3, of input/output ports each adapted to communicate with one or more external computers or networks and to communicate with one of the second number of elements, n3<n2,
means for identifying n3 of the elements which are to be used,
first means for facilitating communication between pairs of one of the n3 elements and one of the n1 devices, and
second means for facilitating communication between pairs of one of the n3 elements and one of the n3 I/O ports.

2. A system for communicating between a number of elements via a data bus, the system comprising:
a data bus,
a first number, n1, of devices adapted to interchange data on the data bus by, repeatedly, a plurality of the devices forwarding data simultaneously to a next device on the data bus,
a second number, n2, of elements each adapted to communicate with one of the devices, n1<n2,
a number, n3, of input/output ports each adapted to communicate with one or more external computers or networks and to communicate with one of the second number of elements,
means for identifying n4<n1 of the elements which are to be used, and
first means for facilitating communication between n4 pairs of one of the n4 elements and one of the n1 devices,
wherein a number of the n1 devices comprises:
means for delaying data received from the data bus before transmission thereof on the bus, and
means for circumventing the delaying means, and
wherein the identifying means are adapted to have the circumventing means circumvent the delaying means in those of the n1 devices not forming part of the n4 pairs.

3. A system according to claim 2, wherein the devices are adapted to:
select one or more data packets to be switched, each data packet being held by a respective device, and
repeatedly, a first number of times:
forward, at least substantially simultaneously, at least part of each of the data packets and pertaining receiving device information to a next device along the interconnecting means,
receive, at least substantially simultaneously and from the interconnecting means, the at least part of the selected data packets and the pertaining receiving device information, and
determine, at least substantially simultaneously in each device having received at least part of a data packet, on the basis of the pertaining receiving device information, whether the at least part of the data packet is intended for the device and, if so, storing a copy of the at least part of the data packet in the device.

4. A testing system for testing a system comprising:
a data bus,
a first number, n1, of devices adapted to interchange data on the data bus,
a second number, n2, of elements each adapted to communicate with one of the devices,
a third number, n3, of input/output ports each adapted to communicate with one or more external computers or networks and to communicate with one of the second number of elements, n3<n2,
means for identifying n4 of the elements which are to be used,
first means for facilitating communication between pairs of one of the n4 elements and one of the n1 devices, and
second means for facilitating communication between pairs of one of the n4 elements and one of the n3 I/O ports,
the testing system comprising:
means for providing power to the system,
means for operating the identifying and facilitating means with n4=n3,
means for determining whether communication is possible from each of the n3 ports to the data bus in the powered system, and
means for, if not, operating the identifying and facilitating means with n4 being a value lower than n3.

5. A system according to claim 4, wherein the means for operating the means for, if not, operating the identifying and facilitating means with n4 being a value lower than n3, are adapted to operate the identifying and facilitating means with n4 being one value of a predetermined set of values each being lower than n3.

6. A system according to claim 4, wherein the elements and the ports are positioned in an at least substantially two-dimensional area of the system, where the ports are distributed along a perimeter of the area, where the sets are defined as sets of ports having predetermined positions along the perimeter of the area, and where the identifying means are adapted to identify n4 functional elements each being adapted to communicate with at least one of the ports of the set.

7. A system according to claim 6, wherein the identifying means are adapted to identify n4 functional elements each being adapted to, via the facilitating means, communicate with only one of the ports of the set.

8. A system according to claim 4, wherein the means for operating the identifying and facilitating means with n4=n3 are adapted to set up a first configuration of the system having each of the n3 ports operable and wherein the facilitating means facilitate that:
each of a first number, n6, of the n3 ports can communicate with at least one element which can communicate with a plurality of the n5 ports and
each of a second number, n7, of the n3 ports can communicate with a plurality of elements which can communicate with only that of the n3 ports.

9. A system according to claim 8, wherein the means for operating the identifying and facilitating means with n4 being a value lower than n3 are adapted to set up a second configuration having each of the n4 ports operable and wherein the facilitating means facilitate that:
each of a first number, n9<n6, of the n4 ports can communicate with at least one element which can communicate with a plurality of the n4 ports and
each of a second number, n10>n7, of the n4 ports can communicate with a plurality of elements which can communicate with only that of the n4 ports.

10. A system comprising:
a data bus,
a first number, n1, of devices adapted to interchange data on the data bus,
a second number, n2, of elements each adapted to communicate with one of the devices,
a third number, n3, of input/output ports each adapted to communicate with one or more external computers or networks and to communicate with one of the second number of elements, n3<n2,
means for identifying which of the elements are functional,
means for determining which of a number of predetermined sets of ports may communicate with the bus via the functional elements,
first means for facilitating communication between pairs of one of the functional elements and one of the n1 devices, and
second means for facilitating communication between pairs of one of the functional elements and one of the I/O ports of the determined set of ports.

11. A system having
a number, n2, of elements adapted to communicate with each other,
a number, n3, of input/output ports each adapted to communicate with one or more external computers or networks and to communicate with one of the number of elements, n3<n2,
means for facilitating communication between pairs of one of the elements and one of the I/O ports,
means for defining:
i. a first configuration having each of a first number, n5<n3, of the ports operable and wherein the facilitating means facilitate that:
1. each of a first number, n6, of the n5 ports can communicate with at least one element which can communicate with a plurality of the n5 ports and
2. each of a second number, n7, of the n5 ports can communicate with a plurality of elements which can communicate with only that of the n5 ports, and
ii. a second configuration having each of a second number, n8<n5, of the ports operable and wherein the facilitating means facilitate that:
1. each of a first number, n9<n6, of the n8 ports can communicate with at least one element which can communicate with a plurality of the n8 ports and
2. each of a second number, n10>n7, of the n8 ports can communicate with a plurality of elements which can communicate with only that of the n8 ports.

12. A system according to claim 11, wherein the elements and the ports are positioned in an at least substantially two-dimensional area of the system, where the ports are distributed along a perimeter of the area, where the n7 ports have predetermined positions along the perimeter of the area, and where the n8 elements each is adapted to communicate with at least one of the n3 ports.

13. A system according to claim 12, further comprising:
a data bus,
a first number, n1, of devices adapted to interchange data on the data bus,
first means for facilitating communication between pairs of one of the n6/n8 elements and one of the n1 devices, and
means for identifying n4 of the elements which are to be used.

14. A system comprising
a number, n2, of elements adapted to communicate with each other,
a number, n3, of input/output ports each adapted to communicate with one or more external computers or networks and to communicate with one of the number of elements, and
a plurality of means each communicatively connected to a plurality of elements and a respective port and being adapted to facilitate communication between one of the respective elements and the respective I/O port,
where the facilitating means comprise:
means for selecting one of the plurality of respective elements communicatively connected thereto and for receiving data there from,
means for receiving a clocking signal from the respective one of the plurality of elements communicatively connected thereto, and
means for outputting the received data to the port in accordance with the clocking signal received.

15. A system comprising
a number, n2, of elements adapted to communicate with each other,
a number, n3, of input/output ports each adapted to communicate with one or more external computers or networks and to communicate with one of the number of elements, and
a plurality of means each communicatively connected to a plurality of elements and a respective port and being adapted to facilitate communication between one of the respective elements and the respective I/O port,
where the facilitating means comprise:
means for selecting one of the plurality of respective elements communicatively connected thereto and for receiving data there from,
means for receiving a clocking signal from the port and transmitting the clocking signal to the selected one of the plurality of respective elements, and
means for outputting the received data to the port in accordance with the clocking signal transmitted.

16. A system comprising
a number, n2, of elements adapted to communicate with each other,
a number, n3, of input/output ports each adapted to communicate with one or more external computers or networks and to communicate with one of the number of elements, and
a plurality of means each communicatively connected to a plurality of ports and a respective element and being adapted to facilitate communication between one of the respective elements and the respective I/O port,
where the facilitating means comprise:
means for selecting one of the plurality of respective ports communicatively connected thereto and for receiving data there from,
means for receiving a clocking signal from the respective one of the plurality of ports communicatively connected thereto, and
means for outputting the received clocking signal to the element as well as the received data in accordance with the clocking signal.

17. A system according to claim 16, wherein the means for outputting comprises at least one register or one FIFO.

18. A system according to claim 16, wherein an I/O port comprises one or more pads adapted to be electrically contacted by surrounding electronics.

19. A system according to claim 14, further comprising:
a data bus,
a first number, n1, of devices adapted to interchange data on the data bus, each of the n2 elements being adapted to communicate with one of the devices,
means for identifying the elements which are to be used, and
first means for facilitating communication between pairs of one of the n3 elements and one of the n1 devices.

20. A system comprising
a number, n2, of elements adapted to communicate with each other,
a number, n3, of input/output ports each adapted to communicate with one or more external computers or networks and to communicate with one of the number of elements,
a plurality of means each communicatively connected to a plurality of elements and a respective port and being adapted to facilitate communication between pairs of one of the elements and one of the I/O ports,
means for providing power and a clocking signal to each element, and
means for removing the clocking signal to one or more elements in order to render the element(s) non-functional.

21. A system according to claim 20, wherein the system comprises CMOS or domino logic elements.

22. A system according to claim 20, further comprising:
a data bus,
a first number, n1, of devices adapted to interchange data on the data bus, each of the n2 elements being adapted to communicate with one of the devices,
means for identifying the elements which are to be used, and
first means for facilitating communication between pairs of one of the n3 elements and one of the n1 devices.

23. A system according to claim 1, wherein the identifying means are adapted to perform the identification on the basis of a result of a self-test of each of the elements.

24. A system according to claim 23, wherein the identifying means comprises testing means operationally connected to each element for receiving the self-test result of the elements and for outputting the results of the self-tests.

25. A system according to claim 24, further comprising central means for receiving the results output and for generating and outputting information for the first and/or second facilitating means.

26. A system according to claim 24, wherein one testing means is provided for each element and for receiving the self-test result from the element and output the self-test result

27. A system according to claim 26, wherein:
one or more of the testing means further comprise means for receiving a self-test result output from another testing means, combining the received self-test result with that received from the pertaining element, and to output the combined test result, and
the first and/or second facilitating means are adapted to receive the test result from a testing means and to operate accordingly.

28. A system according to claim 1, wherein each of the first facilitating means is adapted to provide communication between an element and one of two or more predetermined devices.

29. A system according to claim 1, wherein n2>n1.

30. A system according to claim 1, wherein n1=n3.

31. A system according to claim 1, wherein each of the second facilitating means is adapted to provide communication between an element and one of two or more predetermined devices.

32. A system according to claim 1, wherein n2=n1 and wherein at least one device is adapted to operate in one of two modes, where one mode is a mode where it is adapted to receive data from and transmit data to the data bus and the other mode being one where data received from the data bus is relayed back to the data bus.

33. A system according to claim 32, where each of the first facilitating means facilitates communication between one device and one element.

34. A system according to claim 1, wherein the second facilitating means are interconnected in a daisy chain manner, and where at least part of the second facilitating means are adapted to operate in one of two modes being:
one mode where communication is facilitated between a respective I/O port and an element and
another mode where communication is facilitated between the respective I/O port and a neighbouring, second facilitating means on the daisy chain while communication is facilitated between the respective element and another neighbouring, second facilitating means on the daisy chain.

35. A system according to claim 1, wherein the first facilitating means are interconnected in a daisy chain manner, and where at least part of the first facilitating means are adapted to operate in one of two modes being:
one mode where communication is facilitated between a respective I/O port and an element and
another mode where communication is facilitated between the respective I/O port and a neighbouring, first facilitating means on the daisy chain while communication is facilitated between the respective element and another neighbouring, first facilitating means on the daisy chain.

36. A system according to claim 1, wherein the data bus is a ring bus.

37. A system according to claim 1, wherein at least one of the elements is adapted to:
perform a look-up operation on the basis of at least part of a packet or frame received from an I/O port and to forward at least part of the packet or frame received to a device,
perform packet or frame processing on a packet or frame received from an I/O port,
store a packet or frame received from an 1/0 port before transmission of at least part of the packet or frame to a device.

38. A system according to claim 1, the system being a single chip.

39. A system according to claim 1, the system further comprising means for disabling one or more of the n2 elements, which do not form part of the n3 elements.

40. A system according to claim 39, wherein the system comprises means for providing power to the one or more elements and wherein the disabling means comprise means for cutting off the power to the one or more elements.

41. A system according to claim 39, wherein the system comprises means for providing a clocking signal to the one or more elements and wherein the disabling means comprise means for cutting off the clocking signal to the one or more elements.

42. A system for configuring a system according to claim 1, the system further comprising:
means for determining whether n3 elements are functional,
means for, if so, for each of the n3 functional elements, having the first and second facilitating means facilitate communication between the actual element and a device and between the actual element and an I/O port, respectively,
means for, if not, providing information to the effect that the system is defect.

43. A system according to claim 42, the system further comprising means for disabling one or more of the n2 elements not forming part of the n3 elements.

44. A method of operating a system for communicating between a number of elements via a data bus, the system comprising:
a data bus,
a first number, n1, of devices adapted to interchange data on the data bus,
a second number, n2, of elements each adapted to communicate with one of the devices, n1<n2,
a third number, n3, of input/output ports each adapted to communicate with one or more external computers or networks and to communicate with one of the second number of elements, n3<n2,
the method comprising:
identifying n3 of the elements which are to be used, facilitating communication between pairs of one of the n3 elements and one of the n1 devices, and
facilitating communication between pairs of one of the n3 elements and one of the n3 I/O ports.

45. A method of operating a system for communicating between a number of elements via a data bus, the system comprising:
a data bus having a first number, n1, of devices adapted to interchange data on the data bus by, repeatedly, a plurality of the devices forwarding data simultaneously to a next device on the data bus,
a second number, n2, of elements each adapted to communicate with one of the devices, n1≦n2,
a number, n3, of input/output ports each adapted to communicate with one or more external computers or networks and to communicate with one of the second number of elements,
wherein a number of the n1 devices comprises:
means for delaying data received from the data bus before transmission thereof on the bus, and
means for circumventing the delaying means,
the method comprising:
identifying n4<n1 of the elements which are to be used, facilitating communication between n4 pairs of one of the n4 elements and one of the n1 devices, and
having the circumventing means circumvent the delaying means in those of the n1 devices not forming part of the n4 pairs.

46. A method according to claim 45, further comprising the steps of:
selecting one or more data packets to be switched, each data packet being held by a respective device, and
repeatedly, a first number of times:
forwarding, at least substantially simultaneously, at least part of each of the data packets and pertaining receiving device information to a next device along the interconnecting means,
receiving, at least substantially simultaneously and from the interconnecting means, the at least part of the selected data packets and the pertaining receiving device information, and
determining, at least substantially simultaneously in each device having received at least part of a data packet, on the basis of the pertaining receiving device information, whether the at least part of the data packet is intended for the device and, if so, storing a copy of the at least part of the data packet in the device.

47. A method of testing a system comprising:
a data bus,
a first number, n1, of devices adapted to interchange data on the data bus,
a second number, n2, of elements each adapted to communicate with one of the devices,
a third number, n3, of input/output ports each adapted to communicate with one or more external computers or networks and to communicate with one of the second number of elements, n3<n2,
means for identifying n4 of the elements which are to be used,
first means for facilitating communication between pairs of one of the n4 elements and one of the n1 devices, and second means for facilitating communication between pairs of one of the n4 elements and one of the n3 I/O ports,
the method comprising:
providing power to the system,
operating the identifying and facilitating means with n4=n3,
determining whether communication is possible from each of the n3 ports to the data bus in the powered system, and
if not, operating the identifying and facilitating means with n4 being a value lower than n3.

48. A method according to claim 47, wherein the step of, if not, operating the identifying and facilitating means with n4 being a value lower than n3 comprises operating the identifying and facilitating means with n4 being one value of a predetermined set of values each being lower than n3.

49. A method according to claim 47, wherein the elements and the ports are positioned in an at least substantially two-dimensional area of the system, where the ports are distributed along a perimeter of the area, where the sets are defined as sets of ports having predetermined positions along the perimeter of the area, and where the identifying step comprises identifying n4 functional elements each being adapted to communicate with at least one of the ports of the set.

50. A method according to claim 49, wherein the identifying step comprises identifying n4 functional elements each communicating, via the facilitating means, with only one of the ports of the set.

51. A method according to claim 47, wherein the step of operating the identifying and facilitating means with n4=n3 comprises setting up a first configuration of the system having each of the n3 ports operable and wherein the facilitating means facilitate that:
each of a first number, n6, of the n3 ports can communicate with at least one element which can communicate with a plurality of the n5 ports and
each of a second number, n7, of the n3 ports can communicate with a plurality of elements which can communicate with only that of the n3 ports.

52. A method according to claim 51, wherein the step of operating the identifying and facilitating means with n4 being a value lower than n3 comprises setting up a second configuration having each of the n4 ports operable and wherein the facilitating means facilitate that:
each of a first number, n9<n6, of the n4 ports can communicate with at least one element which can communicate with a plurality of the n4 ports and
each of a second number, n10>n7, of the n4 ports can communicate with a plurality of elements which can communicate with only that of the n4 ports.

53. A method of operating a system comprising:
a data bus,
a first number, n1, of devices adapted to interchange data on the data bus,
a second number, n2, of elements each adapted to communicate with one of the devices,
a third number, n3, of input/output ports each adapted to communicate with one or more external computers or networks and to communicate with one of the second number of elements, n3<n2,
the method comprising:
identifying which of the elements are functional,
determining which of a number of predetermined sets of ports may communicate with the bus via the functional elements,
facilitating communication between pairs of one of the functional elements and one of the n1 devices, and
facilitating communication between pairs of one of the functional elements and one of the I/O ports of the determined set of ports.

54. A method for operating a system having
a number, n2, of elements adapted to communicate with each other,
a number, n3, of input/output ports each adapted to communicate with one or more external computers or networks and to communicate with one of the number of elements, n3<n2,
means for facilitating communication between pairs of one of the elements and one of the I/O ports,
the method comprising:
defining:
i. a first configuration having each of a first number, n5<n3, of the ports operable and wherein the facilitating means facilitate that:
1. each of a first number, n6, of the n5 ports can communicate with at least one element which can communicate with a plurality of the n5 ports and
2. each of a second number, n7, of the n5 ports can communicate with a plurality of elements which can communicate with only that of the n5 ports, and
ii. a second configuration having each of a second number, n8<n5, of the ports operable and wherein the facilitating means facilitate that:
1. each of a first number, n9<n6, of the n8 ports can communicate with at least one element which can communicate with a plurality of the n8 ports and
2. each of a second number, n10>n7, of the n8 ports can communicate with a plurality of elements which can communicate with only that of the n8 ports.

55. A method according to claim 54, wherein the elements and the ports are positioned in an at least substantially two-dimensional area of the system, where the ports are distributed along a perimeter of the area, where the n7 ports have predetermined positions along the perimeter of the area, and where the method comprises the step of the n8 elements each communicating with at least one of the n3 ports.

56. A method according to claim 55, wherein the system further comprises:
a data bus,
a first number, n1, of devices adapted to interchange data on the data bus,
first means for facilitating communication between pairs of one of the n6/n8 elements and one of the n1 devices, and
means for identifying n4 of the elements which are to be used.

57. A method of operating a system comprising
a number, n2, of elements adapted to communicate with each other,
a number, n3, of input/output ports each adapted to communicate with one or more external computers or networks and to communicate with one of the number of elements, and
a plurality of means each communicatively connected to a plurality of elements and a respective port and being adapted to facilitate communication between one of the respective elements and the respective I/O port,
the method comprising the steps of the facilitating means:
selecting one of the plurality of respective elements communicatively connected thereto and receiving data there from,
receiving a clocking signal from the respective one of the plurality of elements communicatively connected thereto, and
outputting the received data to the port in accordance with the clocking signal received.

58. A method of operating a system comprising:
a number, n2, of elements adapted to communicate with each other,
a number, n3, of input/output ports each adapted to communicate with one or more external computers or networks and to communicate with one of the number of elements, and
a plurality of means each communicatively connected to a plurality of elements and a respective port and being adapted to facilitate communication between one of the respective elements and the respective I/O port,
the method comprising the steps of the facilitating means:
selecting one of the plurality of respective elements communicatively connected thereto and receiving data there from,
receiving a clocking signal from the port and transmitting the clocking signal to the one of the plurality of respective elements, and
outputting the received data to the port in accordance with the clocking signal transmitted.

59. A method of operating a system comprising
a number, n2, of elements adapted to communicate with each other,
a number, n3, of input/output ports each adapted to communicate with one or more external computers or networks and to communicate with one of the number of elements, and
a plurality of means each communicatively connected to a plurality of ports and a respective element and being adapted to facilitate communication between one of the respective elements and the respective I/O port,
the method comprising the facilitating means:
selecting one of the plurality of respective ports communicatively connected thereto and receiving data there from,
receiving a clocking signal from the respective one of the plurality of ports communicatively connected thereto, and
outputting the received clocking signal to the element as well as the received data in accordance with the clocking signal.

60. A method of operating a system according to claim 57, wherein the system further comprises:
a data bus,
a first number, n1, of devices adapted to interchange data on the data bus, each of the n2 elements being adapted to communicate with one of the devices,
means for identifying the elements which are to be used, and
first means for facilitating communication between pairs of one of the n3 elements and one of the n1 devices.

61. A method of operating a system comprising
a number, n2, of elements adapted to communicate with each other,
a number, n3, of input/output ports each adapted to communicate with one or more external computers or networks and to communicate with one of the number of elements,
a plurality of means each communicatively connected to a plurality of elements and a respective port and being adapted to facilitate communication between pairs of one of the elements and one of the I/O ports,
the method comprising:
providing power and a clocking signal to each element, and
removing the clocking signal to one or more elements in order to render the element(s) non-functional.

62. A method according to claim 61, the system further comprising:
a data bus,
a first number, n1, of devices adapted to interchange data on the data bus, each of the n2 elements being adapted to communicate with one of the devices,
means for identifying the elements which are to be used, and
first means for facilitating communication between pairs of one of the n3 elements and one of the n1 devices.

63. A method according to claim 44, wherein the identifying step comprises performing the identification on the basis of a result of a self-test of each of the elements.

64. A method according to claim 63, wherein the identifying step comprises testing means operationally connected to each element receiving the self-test result of the elements and outputting the results of the self-tests.

65. A method according to claim 64, further comprising having a central means receiving the results output and generating and outputting information for the first and/or second facilitating means.

66. A method according to claim 64, wherein one testing means provided for each element receives the self-test result from the element and outputs the self-test result

67. A method according to claim 66, wherein:
one or more of the testing means further receives a self-test result output from another testing means, combines the received self-test result with that received from the pertaining element, and outputs the combined test result, and
the first and/or second facilitating means receive the test result from a testing means and operate accordingly.

68. A method according to claim 44, wherein each of the first facilitating means provides communication between an element and one of two or more predetermined devices.

69. A method according to claim 44, wherein each of the second facilitating means provides communication between an element and one of two or more predetermined devices.

70. A method according to claim 44, wherein n2=n1 and wherein at least one device operates in one of two modes, where one mode is a mode where it is adapted to receive data from and transmit data to the data bus and the other mode being one where data received from the data bus is relayed back to the data bus.

71. A method according to claim 70, where each of the first facilitating means facilitates communication between one device and one element.

72. A method according to claim 44, wherein the second facilitating means are interconnected in a daisy chain manner, and where at least part of the second facilitating means operates in one of two modes being:
one mode where communication is facilitated between a respective I/O port and an element and
another mode where communication is facilitated between the respective I/O port and a neighbouring, second facilitating means on the daisy chain while communication is facilitated between the respective element and another neighbouring, second facilitating means on the daisy chain.

73. A method according to claim 44, wherein the first facilitating means are interconnected in a daisy chain manner, and where at least part of the first facilitating means operates in one of two modes being:
one mode where communication is facilitated between a respective I/O port and an element and
another mode where communication is facilitated between the respective I/O port and a neighbouring, first facilitating means on the daisy chain while communication is facilitated between the respective element and another neighbouring, first facilitating means on the daisy chain.

74. A method according to claim 44, wherein at least one of the elements:
perform a look-up operation on the basis of at least part of a packet or frame received from an I/O port and to forward at least part of the packet or frame received to a device,
perform packet or frame processing on a packet or frame received from an I/O port,
store a packet or frame received from an I/O port before transmission of at least part of the packet or frame to a device.

75. A method according to claim 44, the system further comprising the step of disabling one or more of the n2 elements, which do not form part of the n3 elements.

76. A method according to claim 75, comprising the steps of providing power to the one or more elements and cutting off the power to the one or more elements.

77. A method according to claim 75, comprising the steps of providing a clocking signal to the one or more elements and cutting off the clocking signal to the one or more elements.

78. A method for configuring a system according to claim 44, the method further comprising:
determining whether n3 elements are functional,
if so, for each of the n3 functional elements, having the first and second facilitating means facilitate communication between the actual element and a device and between the actual element and an I/O port, respectively,
if not, providing information to the effect that the system is defect.

79. A method according to claim 78, further comprising disabling one or more of the n2 elements not forming part of the n3 elements.
